(19) United States
(12) Patent Application Publication
(10) Pub. No.: US 2024/0196646 A1
(43) Pub. Date: Jun. 13, 2024

(54) ORGANIC LIGHT-EMITTING DIODE DISPLAY PANEL AND MANUFACTURING METHOD THEREOF

(71) Applicant: Shenzhen China Star Optoelectronics Semiconductor Display Technology Co., Ltd., Shenzhen (CN)

(72) Inventor: Wei TAN, Shenzhen (CN)

(21) Appl. No.: 18/469,074

(22) Filed: Sep. 18, 2023

(30) Foreign Application Priority Data
Dec. 7, 2022 (CN) 202211561444.3

(51) Int. Cl. H10K 59/12; H10K 59/122; H10K 59/131; H10K 59/80; H10K 71/16; H10K 71/60

(52) U.S. Cl. CPC H10K 59/1201; H10K 59/122; H10K 59/131; H10K 59/873; H10K 71/164; H10K 71/166; H10K 71/60

(57) ABSTRACT

An organic light-emitting diode (OLED) display panel and a manufacturing method thereof are provided. A pad of the OLED display panel includes a first metal layer and a second metal layer stacked. An edge of the second metal layer protrudes from an edge of the first metal layer. An electronic functional layer covered on the second metal layer is disconnected from the electronic functional layer covered on an array structure layer, so that a cathode covers a side of the second metal layer adjacent to the array structure layer to realize an electrical connection between the cathode and the pad.

### CROSS-REFERENCE TO RELATED APPLICATION

This application claims priority to and the benefit of Chinese Patent Application No. 202211561444.3, filed on Dec. 7, 2022, the disclosure of which is incorporated herein by reference in its entirety.

### TECHNICAL FIELD

The present disclosure relates to display technologies, and in particular, to an organic light-emitting diode (OLED) display panel and a manufacturing method thereof.

### BACKGROUND

Organic light-emitting diodes (OLED) have advantages such as simple structure, self-luminescence, fast response speed, ultra-thin, and low power consumption. OLED displays devices are being vigorously developed by major display manufacturers. OLED display panels have become a most potential and competitive competitor in the future because of their excellent characteristics such as high contrast, wide color gamut, fast response speed, and flexibility. At present, the OLED display panels are generally manufactured by a vacuum evaporation process, which has strict process requirements and high cost. Large-size and high-precision metal masks (Fine Metal Mask, FMM) have related technical difficulties that may not be overcome, which limits a large-scale popularization and application of the FMM in larger-size products.

At present, a red-green-blue pixel array on a large-size glass substrate at normal temperature and pressure may be quickly and continuously manufactured by an ink-jet printing technology, which creates conditions for large-size OLED display devices. However, at present, the printing technology is in its infancy, and all films in OLED devices may not adopt the printing technology due to material limitations. A hole functional layer and a light-emitting material layer may adopt the printing display technology to avoid the difficulties of an evaporation FMM process, but film layers such as an electronic functional layer and a cathode still need evaporation or SPT film formation technology to realize mass production.

At present, an opening of an evaporation mask of the electronic functional layer is generally smaller than an opening of the cathode to realize a normal overlap between the cathode and a pad. At this time, two kinds of masks are needed to manufacture the electronic functional layer and the cathode respectively. Moreover, a current mass production equipment uses two sets of evaporative plating cycle systems to manufacture the electronic functional layer film layers and the cathode respectively, which leads to high investment cost of an evaporation equipment.

### SUMMARY

An organic light-emitting diode (OLED) display panel and a manufacturing method thereof are provided by the present application, to solve a technical problem that investment cost of an evaporation equipment is relatively high in the prior art, when an electronic functional layer and a cathode are manufactured by using two kinds of mask plates respectively.

To solve above technical problem, the present application provides an OLED display panel including a display area and a bonding area. The OLED display panel further includes a substrate, an array structure layer, a pad, an anode, a pixel defining layer, a light-emitting material layer, an electronic functional layer, and a cathode. The array structure layer is disposed on the substrate. The pad is disposed on a side of the array structure layer away from the substrate and located in the bonding area. The pad includes a first metal layer and a second metal layer stacked. The second metal layer is disposed on a side of the first metal layer away from the array structure layer, and an edge of the second metal layer protrudes from an edge of the first metal layer. The anode is disposed on the side of the array structure layer away from the substrate and located in the display area. The pixel defining layer is disposed on a side of the anode away from the substrate, extends to cover the array structure layer, and located in the display area. The pixel defining layer is provided with a pixel hole at a position corresponding to the anode. The light-emitting material layer is disposed in the pixel hole of the pixel definition layer. An electronic functional layer is disposed on the light-emitting material layer, and extends to cover the pixel definition layer, the array structure layer, and the pad. The electronic functional layer covered on the second metal layer is disconnected from the electronic functional layer covered on the array structure layer. The cathode is disposed on a side of the electronic functional layer away from the array structure layer and directly covering a side of the second metal layer adjacent to the array structure layer.

In some embodiments, a thickness of the electronic functional layer located in the bonding area is less than a thickness of the first metal layer.

In some embodiments, the thickness of the first metal layer is less than or equal to a sum of the thickness of the electronic functional layer located in the bonding area and a thickness of the cathode.

In some embodiments, the electronic functional layer includes an electron transport layer and an electron injection layer. The electron transport layer is disposed on a side of the light-emitting material layer away from the anode. The electron injection layer is disposed on a side of the electron transport layer away from the light-emitting material layer.

In some embodiments, the pad further includes a third metal layer disposed on a side of the second metal layer away from the first metal layer, and the edge of the second metal layer protrudes from an edge of the third metal layer.

In some embodiments, the OLED display panel further includes an encapsulation layer disposed on a side of the cathode away from the array structure layer.

To solve above technical problem, the present application further provides a method of manufacturing an OLED display panel including following manufacturing steps: providing a substrate and defining a display area and a bonding area on the substrate; forming an array structure layer on the substrate; forming an anode and a pad on a side of the array structure layer away from the substrate, the pad is located on the bonding area, and the anode is located in the display area; the pad includes a first metal layer and a second metal layer stacked, the second metal layer is disposed on a side of the first metal layer away from the array structure layer, and an etching amount of the first metal layer is greater than an etching amount of the second metal layer to make that an edge of the second metal layer protrudes from an edge of the first metal layer; forming a pixel defining layer on a side of the anode away from the substrate, the pixel defining layer extends to cover the array structure layer and is located in the display area, and the pixel defining layer is provided with a pixel hole at a position corresponding to the anode; forming a light-emitting material layer in the pixel hole of the pixel definition layer; forming an electronic functional layer on the light-emitting material layer, the electronic functional layer extends to cover the pixel definition layer, the array structure layer, and the pad; the electronic functional layer covered the second metal layer is disconnected from the electronic functional layer covered the array structure layer; and forming a cathode on a side of the electronic functional layer away from the array structure layer, the cathode covers a side of the second metal layer adjacent to the array structure layer.

In some embodiments, a step of forming the electronic functional layer includes: providing a mask plate and forming the electronic functional layer on the light-emitting material layer with an evaporation angle α through the mask plate, the electronic functional layer further extends on the pixel definition layer, the array structure layer, and the pad; a thickness of the electronic functional layer located in the bonding area is less than a thickness of the first metal layer.

In some embodiments, a step of forming the cathode includes: forming the cathode on the side of the electronic functional layer away from the array structure layer with an evaporation angle β, the cathode covers a side of the second metal layer adjacent to the array structure layer, the thickness of the first metal layer is less than or equal to a sum of the thickness of the electronic functional layer located in the bonding area and a thickness of the cathode.

In some embodiments, the evaporation angle α is greater than the evaporation angle β.

Beneficial effects of the present application are that: the pad of the present application includes a first metal layer and a second metal layer stacked, and the edge of the second metal layer protrudes from the edge of the first metal layer. The pad in the bonding area is designed as an “undercut” structure, so that the electronic functional layer covered on the second metal layer is disconnected from the electronic functional layer covered on the array structure layer, and the cathode is covered on the second metal layer near the array structure layer to realize an electrical connection between the cathode and the pad. By adjusting the evaporation angle and adopting a same mask plate to manufacture the electronic functional layer and the cathode respectively, evaporation processes, a circuit equipment configuration of a production line, and investment cost of the production line may be reduced, on the basis of not affecting a lapped effect of the cathode and the pad.

### BRIEF DESCRIPTION OF THE DRAWINGS

To describe the technical solutions of the embodiments of the present application more clearly, the following briefly introduces the accompanying drawings used in the description of the embodiments of the present application. Apparently, the accompanying drawings described below illustrate only some exemplary embodiments of the present application, and persons skilled in the art may derive other drawings from the drawings without making creative efforts.

FIG. 1 is a schematic structural diagram of an organic light-emitting diode (OLED) display panel provided by an embodiment of the present application.

FIG. 2 is an enlarged diagram of Part A in FIG. 1.

FIG. 3 is a flowchart of a manufacturing method of the OLED display panel according to an embodiment of the present application.

FIG. 4 is a schematic diagram of an array structure layer, a pad, an anode, and a pixel definition layer manufactured by the present application on a substrate.

FIG. 5 is a schematic diagram of manufacturing a light-emitting material layer based on FIG. 4.

FIG. 6 is a schematic diagram of manufacturing an electronic functional layer based on FIG. 5.

FIG. 7 is a schematic diagram of an evaporation angle when the electronic functional layer is evaporated according to an embodiment of the present application.

FIG. 8 is a schematic diagram of an evaporation angle when a cathode is evaporated according to an embodiment of the present application.

### DETAILED DESCRIPTION

The technical solutions in the present application will be described clearly and completely hereafter with reference to the accompanying drawings. Apparently, the described embodiments are only a part of but not all embodiments of the present application. All other embodiments obtained by persons of ordinary skill in the art based on the embodiments of the present application without creative efforts shall fall within the protection scope of the present application. Furthermore, it should be understood that the specific embodiments described herein are intended to illustrate and explain the present application only and are not intended to limit the present application. In the present application, location terms such as “up” and “down” are used in general to refer to up and down in actual use or operation of the device, in particular, the drawing direction in the drawings, without a description to the contrary, while “inside” and “outside” are for the outline of the device.

The present application provides an organic light-emitting diode (OLED) display panel and a manufacturing method thereof. Details will be explained below.

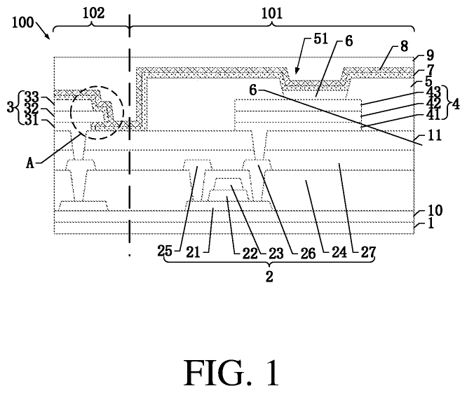

Referring to FIG. 1, an embodiment of the present application provides an OLED display panel 100. The OLED display panel 100 may include a display area 101 and a bonding area 102 by functional division. The OLED display panel 100 may include a substrate 1, an array structure layer 2, a pad 3, an anode 4, a pixel definition layer 5, a light-emitting material layer 6, an electronic functional layer 7, a cathode 8, and an encapsulation layer 9.

A material of the substrate 1 is selected from one or more of glass, polyimide, polycarbonate, polyethylene terephthalate, and polyethylene naphthalate, so that the substrate 1 may have better impact resistance to effectively protect the OLED display panel 100. In this embodiment, the substrate 1 is a glass substrate to support film structures.

Referring to FIG. 1, a buffer layer 10 is disposed on the substrate 1. The buffer layer 10 mainly plays a buffering role, and a material of the buffer layer 10 may selected from SiOx, SiNx, SiNOx, or a combined structure of SiNx and SiOx.

The array structure layer 2 is disposed on a side of the buffer layer 10 away from the substrate 1. The array structure layer 2 includes an active layer 21, a gate insulating layer 22, a gate layer 23, an interlayer insulating layer 24, a source electrode 25, a drain electrode 26, and a passivation layer 27.

A planarization layer 11 is further disposed on the array structure layer. A material of the planarization layer 11 may be SiOx, SiNx, SiNOx, or the combined structure of SiNx and SiOx. The planarization layer 11 mainly provides a flat surface for manufacturing the film layers thereon.

The pad 3 is disposed on a side of the array structure layer 2 away from the substrate 1 and located in the bonding area 102. The pad 3 is mainly used for externally connecting driving signals.

Referring to FIG. 1, in this embodiment, the pad 3 includes a first metal layer 31, a second metal layer 32, and a third metal layer 33 stacked. In an embodiment, the first metal layer 31 is disposed on the side of the array structure layer 2 away from the substrate 1 and located in the bonding area 102. The second metal layer 32 is disposed on a side of the first metal layer 31 away from the array structure layer 2. The third metal layer 33 is disposed on a side of the second metal layer 32 away from the first metal layer 31. An edge of the second metal layer 32 protrudes from an edge of the first metal layer 31. The edge of the second metal layer 32 protrudes from an edge of the third metal layer 33.

In an embodiment, a material of the second metal layer 32 is different from a material of the first metal layer 31, the material of the second metal layer 32 is different from a material of the third metal layer 33, and the material of the first metal layer 31 may be same or different from the material of the third metal layer 33. An etching amount of the second metal layer 32 is less than an etching amount of the first metal layer 31, and the etching amount of the second metal layer 32 is less than an etching amount of the third metal layer 33, so that an outer edge of the second metal layer 32 protrudes from an outer edge of the first metal layer 31, and the outer edge of the second metal layer 32 protrudes from an outer edge of the third metal layer 33.

In summary, the outer edge of the second metal layer 32 protrudes from the outer edge of the first metal layer 31, so that the pad 3 in the bonding area 102 is designed as an “undercut” structure, so that the electronic functional layer covered on the second metal layer 32 is disconnected from the electronic functional layer 7 covered on the array structure layer 2, and the cathode 8 is covered on the second metal layer 32 adjacent to the array structure layer 2 to realize an electrical connection between the cathode 8 and the pad 3. By adjusting an evaporation angle and adopting a same mask plate to manufacture the electronic functional layer 7 and the cathode 8 respectively, evaporation processes, a circuit equipment configuration of a production line, and investment cost of the production line may be reduced on the basis of not affecting a lapped effect of the cathode 8 and the pad 3.

In other embodiments, the pad 3 may include only the first metal layer 31 and the second metal layer 32 stacked.

The anode 4 is disposed on the side of the array structure layer 2 away from the substrate 1 and located in the display area 101. In this embodiment, the anode 4 includes a first film layer 41, a second film layer 42, and a third film layer 43. In an embodiment, the first film layer 41 is disposed on the side of the array structure layer 2 away from the substrate 1, and located in the display area 101. The second film layer 42 is disposed on a side of the first film layer 41 away from the array structure layer 2, and the third film layer 43 is disposed on a side of the second film layer 42 away from the first film layer 41. In this embodiment, a material of the first film layer 41 and the material of the first metal layer 31, so that the first film layer 41 and the first metal layer 31 may be manufactured in a same process to optimize the preparation process. In this embodiment, a material of the second film layer 42 and the material of the second metal layer 32 are same, so that the second film layer 42 and the second metal layer 32 may be manufactured in a same process to optimize the preparation process. A material of the third film layer 43 and the material of the third metal layer 33 are same, so that the third film layer 43 and the third metal layer 33 may be manufactured in a same process to optimize the preparation process.

In other embodiments, the material of the first film layer 41 may be different from the material of the first metal layer 31, the material of the second film layer 42 may be different from the material of the second metal layer 32, and the material of the third film layer 43 may be different from the material of the third metal layer 33.

The pixel defining layer 5 is disposed on a side of the anode 4 away from the substrate 1, extends to cover the array structure layer 2, and located in the display area 101. The pixel defining layer 5 is provided with a pixel hole 51 at a position corresponding to the anode 4, that is, the anode 4 is not covered by the pixel defining layer 5 at the position corresponding to the pixel hole 51 and exposed, so that the anode 4 is connected with subsequent film layers. To avoid poor contact at an edge of the anode 4, a bottom size of the pixel hole 51 is less than a size of the anode 4 to ensure that the edge of the anode 4 is still covered by the pixel definition layer 5.

The light-emitting material layer 6 is disposed in the pixel hole 51 of the pixel definition layer 5. Actually, a hole functional layer (not shown in the figures) is further disposed between the light-emitting material layer 6 and the anode 4. The hole functional layer includes a hole injection layer, hole transport layer, etc.

The electronic functional layer 7 is disposed on the light-emitting material layer 6, and extends to cover the pixel definition layer, the array structure layer 2, and the pad 3. The electronic functional layer 7 includes an electron transport layer (not shown in the figures) disposed on a side of the light-emitting material layer 6 away from the anode 4. An electron injection layer (not shown in the figures) disposed on a side of the electron transport layer away from the light-emitting material layer 6.

The electronic functional layer 7 covered on the second metal layer 32 is disconnected from the electronic functional layer 7 covered on the array structure layer 2. In an embodiment, the electronic functional layer 7 covered on the second metal layer 32 is disconnected from the electronic functional layer 7 covered on the planarization layer 11. The cathode 8 is covered on the side of the second metal layer 32 adjacent to the array structure layer 2, thereby realizing the electrical connection between the cathode 8 and the pad 3. By adjusting the evaporation angle and using the same mask plate to prepare the electronic functional layer 7 and the cathode 8 respectively, the evaporation process may be reduced, the circuit equipment configuration of the production line may be reduced, and the investment cost of the production line may be reduced without affecting the lap effect of the cathode 8 and the pad 3.

The cathode 8 is disposed on a side of the electronic functional layer 7 away from the array structure layer 2 and covering the side of the second metal layer adjacent to the array structure layer to realize the electrical connection between the cathode 8 and the pad 3.

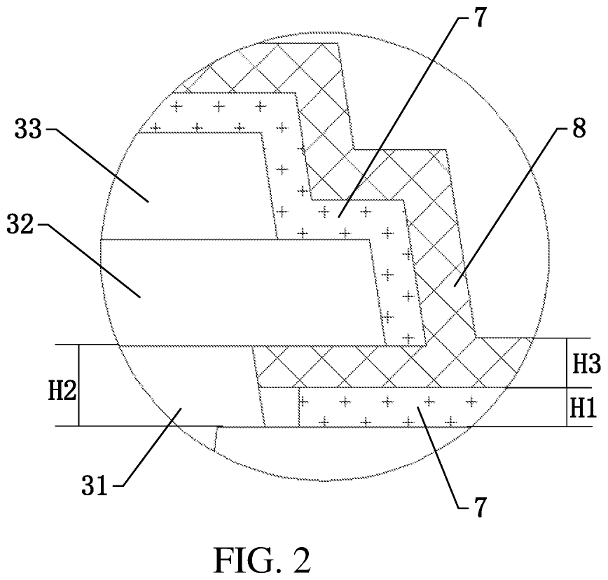

Referring to FIG. 2, a thickness of the cathode is H3, and H3 is less than or equal to a sum of H1 and H3, which ensures that the cathode 8 covers the side of the second metal layer adjacent to the array structure layer to realizing the electrical connection between the cathode 8 and the pad 3.

The encapsulation layer 9 is disposed on a side of the cathode away from the array structure layer. In an embodiment, the encapsulation layer 9 may include a first inorganic encapsulation layer (not shown in the figures), an organic encapsulation layer (not shown in the figures), and a second inorganic encapsulation layer (not shown in the figures). The encapsulation layer 9 is mainly used for protecting each metal film layer covered by the encapsulation layer 9 to avoid a technical problem that life of the metal film layer is reduced due to an invasion of external water vapor. The encapsulation layer 9 is a transparent material to reduce a light loss of the light-emitting material layer 6.

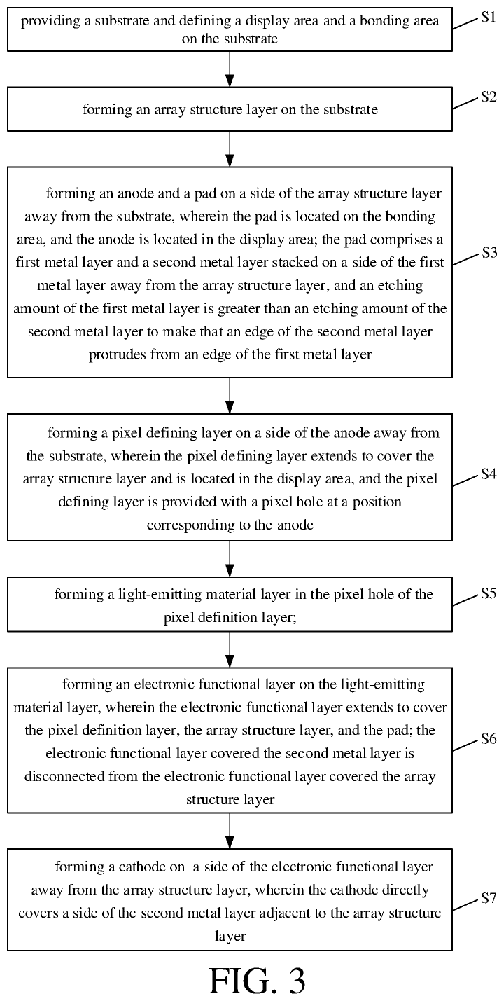

Referring to FIG. 3, the present application further provides a method of manufacturing an OLED display panel including manufacturing steps as follows: S1, providing a substrate and defining a display area and a bonding area on the substrate. S2, forming an array structure layer on the substrate; S3, forming an anode and a pad on a side of the array structure layer away from the substrate, the pad is located on the bonding area, and the anode is located in the display area; the pad includes a first metal layer and a second metal layer stacked on a side of the first metal layer away from the array structure layer, and an etching amount of the first metal layer is greater than an etching amount of the second metal layer to make that an edge of the second metal layer protrudes from an edge of the first metal layer. S4, forming a pixel defining layer on a side of the anode away from the substrate, the pixel defining layer extends to cover the array structure layer and is located in the display area, and the pixel defining layer is provided with a pixel hole at a position corresponding to the anode. S5, forming a light-emitting material layer in the pixel hole of the pixel definition layer. S6, forming an electronic functional layer on the light-emitting material layer, the electronic functional layer extends to cover the pixel definition layer, the array structure layer, and the pad, the electronic functional layer covered the second metal layer is disconnected from the electronic functional layer covered the array structure layer. S7, forming a cathode on a side of the electronic functional layer away from the array structure layer, the cathode covers a side of the second metal layer adjacent to the array structure layer.

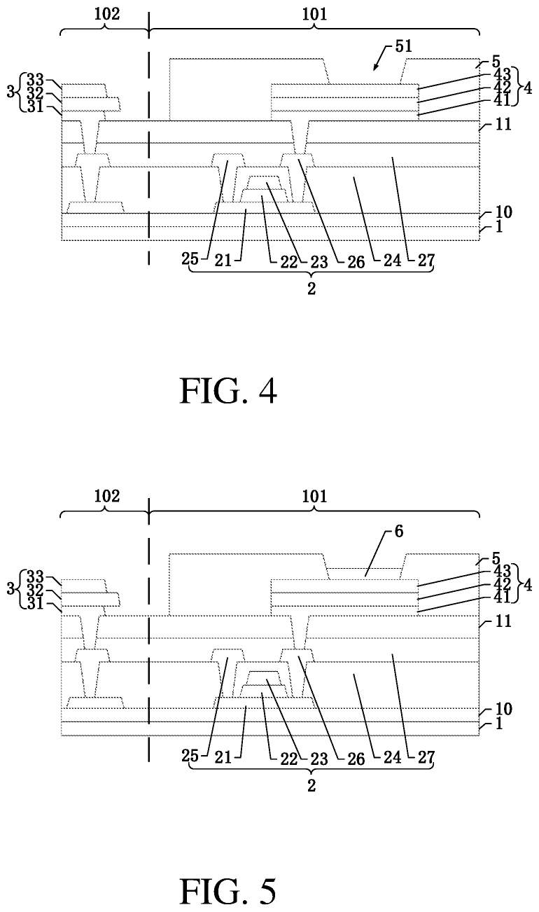

Referring to FIG. 4, the pad 3 further includes a third metal layer 33 stacked with the first metal layer 31 and second metal layer 32. An etching amount of the third metal layer 31 is greater than the etching amount of the second metal layer 32 to make that the edge of the second metal layer 32 protrudes from the edge of the third metal layer;

Referring to FIG. 5, the light-emitting material is printed only on the anode 4 in the pixel hole 51 of the pixel definition layer 5 to form the light-emitting material layer 6.

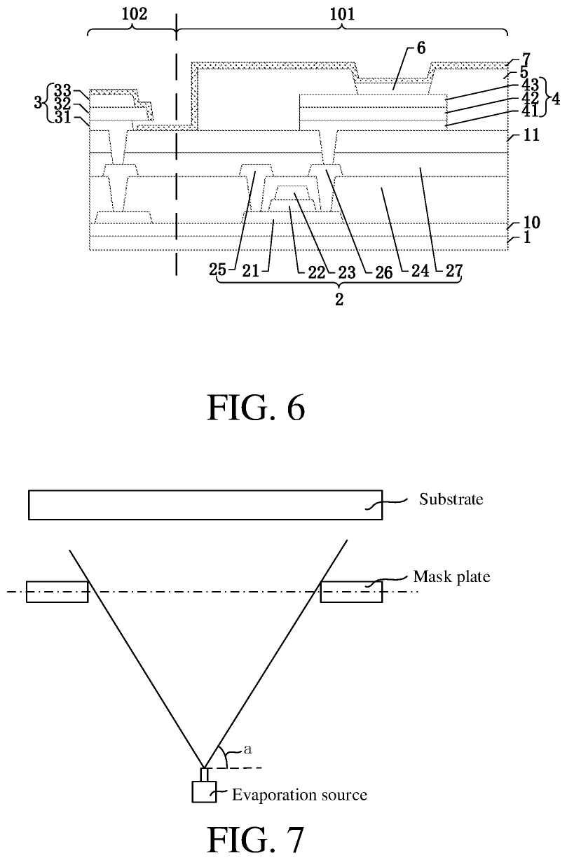

Referring to FIG. 2, FIG. 6, and FIG. 7, in the S6, providing a mask plate and forming the electronic functional layer 7 on the light-emitting material layer 6 with an evaporation angle α through the mask plate, and the electronic functional layer 7 further extends on the pixel definition layer 5, the array structure layer 2, and the pad 3. A thickness of the electronic functional layer 7 located in the bonding area 102 is H1. A thickness of the first metal layer 31 is H2. H1 is less than H2. This ensures that the electronic functional layer 7 covered on the second metal layer 32 is disconnected from the electronic functional layer 7 covered on the planarization layer 11. The cathode 8 is covered on the side of the second metal layer 32 adjacent to the array structure layer 2, thereby realizing the electrical connection between the cathode 8 and the pad 3.

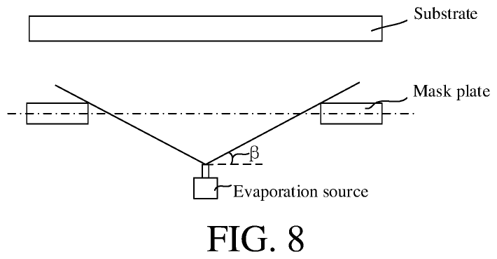

Referring to FIG. 2, FIG. 6, and FIG. 8, in the S7, forming the cathode 8 on the side of the electronic functional layer 7 away from the array structure layer 2 with an evaporation angle β. The cathode 8 covers a side of the second metal layer 32 adjacent to the array structure layer 2. A thickness of the cathode 8 is H3, and H2 is less than or equal to a sum of H1 and H3.

In summary, by adjusting the evaporation angle and using the same mask plate to prepare the electronic functional layer 7 and the cathode 8 respectively, the evaporation process may be reduced, the circuit equipment configuration of the production line may be reduced, and the investment cost of the production line may be reduced without affecting the lap effect of the cathode 8 and the pad 3.

The present disclosure has been described in detail with respect to an OLED display panel and a manufacturing method therefore according to an embodiment of the present disclosure. The principles and implementations of the present disclosure are described in detail here with specific examples. The above description of the embodiments is merely intended to help understand the method and core ideas of the present application. At the same time, a person skilled in the art may make changes in the specific embodiments and application scope according to the idea of the present application. In conclusion, the content of the present specification should not be construed as a limitation to the present disclosure.

What is claimed is:

1. An organic light-emitting diode (OLED) display panel, comprising a display area and a bonding area, and further comprising:
a substrate;
a buffer layer, disposed on the substrate;
an array structure layer, disposed on a side of the buffer layer away from the substrate;
a pad, disposed on a side of the array structure layer away from the substrate and located in the bonding area, wherein the pad comprises a first metal layer and a second metal layer stacked, the second metal layer is disposed on a side of the first metal layer away from the array structure layer, and an edge of the second metal layer protrudes from an edge of the first metal layer;
an anode, disposed on the side of the array structure layer away from the substrate and located in the display area;
a pixel defining layer, disposed on a side of the anode away from the substrate, extending to cover the array structure layer, and located in the display area, wherein the pixel defining layer is provided with a pixel hole at a position corresponding to the anode;
a light-emitting material layer, disposed in the pixel hole of the pixel definition layer;
an electronic functional layer, disposed on the light-emitting material layer, and extending to cover the pixel definition layer, the array structure layer, and the pad; wherein the electronic functional layer covered on the second metal layer is disconnected from the electronic functional layer covered on the array structure layer; and
a cathode, disposed on a side of the electronic functional layer away from the array structure layer and covering a side of the second metal layer adjacent to the array structure layer.

2. The OLED display panel according to claim 1, wherein a thickness of the electronic functional layer located in the bonding area is less than a thickness of the first metal layer.

3. The OLED display panel according to claim 2, wherein the thickness of the first metal layer is less than or equal to a sum of the thickness of the electronic functional layer located in the bonding area and a thickness of the cathode.

4. The OLED display panel according to claim 1, wherein the electronic functional layer comprises:
an electron transport layer, disposed on a side of the light-emitting material layer away from the anode; and
an electron injection layer, disposed on a side of the electron transport layer away from the light-emitting material layer.

5. The OLED display panel according to claim 1, wherein the pad further comprises a third metal layer disposed on a side of the second metal layer away from the first metal layer, and the edge of the second metal layer protrudes from an edge of the third metal layer.

6. The OLED display panel according to claim 5, wherein the anode comprises:
a first film layer, disposed on the side of the array structure layer away from the substrate;
a second film layer, disposed on a side of the first film layer away from the array structure layer; and
a third film layer, disposed on a side of the second film layer away from the first film layer.

7. The OLED display panel according to claim 6, wherein a material of the first film layer and a material of the first film layer are same, a material of the second film layer and a material of the second film layer are same, and a material of the third film layer and a material of the third film layer are same.

8. The OLED display panel according to claim 1, further comprising:
an encapsulation layer, disposed on a side of the cathode away from the array structure layer.

9. An organic light-emitting diode (OLED) display panel, comprising a display area and a bonding area, and further comprising:
a substrate;
an array structure layer, disposed on the substrate;
a pad, disposed on a side of the array structure layer away from the substrate and located in the bonding area, wherein the pad comprises a first metal layer and a second metal layer stacked, the second metal layer is disposed on a side of the first metal layer away from the array structure layer, and an edge of the second metal layer protrudes from an edge of the first metal layer;
an anode, disposed on the side of the array structure layer away from the substrate and located in the display area;
a pixel defining layer, disposed on a side of the anode away from the substrate, extending to cover the array structure layer, and located in the display area, wherein the pixel defining layer is provided with a pixel hole at a position corresponding to the anode;
a light-emitting material layer, disposed in the pixel hole of the pixel definition layer;
an electronic functional layer, disposed on the light-emitting material layer, and extending to cover the pixel definition layer, the array structure layer, and the pad; wherein the electronic functional layer covered on the second metal layer is disconnected from the electronic functional layer covered on the array structure layer; and
a cathode, disposed on a side of the electronic functional layer away from the array structure layer and covering a side of the second metal layer adjacent to the array structure layer.

10. The OLED display panel according to claim 9, wherein a thickness of the electronic functional layer located in the bonding area is less than a thickness of the first metal layer.

11. The OLED display panel according to claim 10, wherein the thickness of the first metal layer is less than or equal to a sum of the thickness of the electronic functional layer located in the bonding area and a thickness of the cathode.

12. The OLED display panel according to claim 9, wherein the electronic functional layer comprises:
an electron transport layer, disposed on a side of the light-emitting material layer away from the anode; and
an electron injection layer, disposed on a side of the electron transport layer away from the light-emitting material layer.

13. The OLED display panel according to claim 9, wherein the pad further comprises a third metal layer disposed on a side of the second metal layer away from the first metal layer, and the edge of the second metal layer protrudes from an edge of the third metal layer.

14. The OLED display panel according to claim 9, wherein the anode comprises:
a first film layer, disposed on the side of the array structure layer away from the substrate;
a second film layer, disposed on a side of the first film layer away from the array structure layer; and
a third film layer, disposed on a side of the second film layer away from the first film layer.

15. The OLED display panel according to claim 14, wherein a material of the first film layer and a material of the first film layer are same, a material of the second film layer and a material of the second film layer are same, and a material of the third film layer and a material of the third film layer are same.

16. The OLED display panel according to claim 9, further comprising:
an encapsulation layer, disposed on a side of the cathode away from the array structure layer.

17. A method of manufacturing an OLED display panel, comprising:
providing a substrate and defining a display area and a bonding area on the substrate;
forming an array structure layer on the substrate;
forming an anode and a pad on a side of the array structure layer away from the substrate, wherein the pad is located on the bonding area, and the anode is located in the display area; the pad comprises a first metal layer and a second metal layer on a side of the first metal layer away from the array structure layer, and an etching amount of the first metal layer is greater than an etching amount of the second metal layer to make that an edge of the second metal layer protrudes from an edge of the first metal layer;
forming a pixel defining layer on a side of the anode away from the substrate, wherein the pixel defining layer extends to cover the array structure layer and is located in the display area, and the pixel defining layer is provided with a pixel hole at a position corresponding to the anode;
forming a light-emitting material layer in the pixel hole of the pixel definition layer;
forming an electronic functional layer on the light-emitting material layer, wherein the electronic functional layer extends to cover the pixel definition layer, the array structure layer, and the pad; the electronic functional layer covered the second metal layer is disconnected from the electronic functional layer covered the array structure layer; and
forming a cathode on a side of the electronic functional layer away from the array structure layer, wherein the cathode covers a side of the second metal layer adjacent to the array structure layer.

18. The method of manufacturing an OLED display panel according to claim 17, wherein a step of forming the electronic functional layer comprises:
providing a mask plate and forming the electronic functional layer on the light-emitting material layer with an evaporation angle α through the mask plate, wherein the electronic functional layer further extends on the pixel definition layer, the array structure layer, and the pad;
wherein a thickness of the electronic functional layer located in the bonding area is less than a thickness of the first metal layer.

19. The method of manufacturing an OLED display panel according to claim 17, wherein a step of forming the cathode comprises:
forming the cathode on the side of the electronic functional layer away from the array structure layer with an evaporation angle β, wherein the cathode covers a side of the second metal layer adjacent to the array structure layer, the thickness of the first metal layer is less than or equal to a sum of the thickness of the electronic functional layer located in the bonding area and a thickness of the cathode.

20. The method of manufacturing an OLED display panel according to claim 17, wherein the evaporation angle α is greater than the evaporation angle β.
